(19) United States
(12) Patent Application Publication
(10) Pub. No.: US 2022/0347913 A1
(43) Pub. Date: Nov. 3, 2022

(54) PATTERN FORMING METHOD AND METHOD OF PRODUCING CURABLE COMPOSITION

(71) Applicant: TOKYO OHKA KOGYO CO., LTD., Kawasaki-shi (JP)

(72) Inventors: Takeshi IWAI, Kawasaki-shi (JP); Kenri KONNO, Kawasaki-shi (JP); Yohei AOYAMA, Kawasaki-shi (JP); Risako MORI, Kawasaki-shi (JP)

(21) Appl. No.: 17/659,947

(22) Filed: Apr. 20, 2022

(30) Foreign Application Priority Data
Apr. 28, 2021 (JP) 2021-076543

(51) Int. Cl. B29C 59/02; B29C 35/08

(52) U.S. Cl. CPC B29C 59/026; B29C 59/022; B29C 35/0805; B29K 2105/162

(57) ABSTRACT

A pattern forming method including forming a curable film using a curable composition that contains metal oxide nanoparticles, on a substrate, pressing a mold having a line and space pattern against the curable film to transfer the line and space pattern to the curable film, curing the curable film to which the line and space pattern has been transferred while pressing the mold against the curable film, to form a cured film, and peeling the mold off the cured film to form a line and space pattern on the substrate, in which a line width x of the line and space pattern formed on the substrate in a base portion and a volume average primary particle diameter φ of the metal oxide nanoparticles satisfy an expression of 0.03x<φ<0.08x, and an expression of x≤500 nm.

### BACKGROUND OF THE INVENTION

### Field of the Invention

The present invention relates to a pattern forming method and a method of producing a curable composition.

Priority is claimed on Japanese Patent Application No. 2021-076543, filed on Apr. 28, 2021, the content of which is incorporated herein by reference.

### Description of Related Art

A lithography technology is a core technology in the process of manufacturing semiconductor devices, and with the recent increase in the integration of semiconductor integrated circuits (IC), further miniaturization of wiring is progressing. Typical examples of the miniaturization method include shortening the wavelength of a light source using a light source having a shorter wavelength such as a KrF excimer laser, an ArF excimer laser, an F₂ laser, extreme ultraviolet light (EUV), an electron beam (EB), or an X-ray, and increasing the diameter (increase in NA) of the numerical aperture (NA) of a lens of an exposure device.

Under the above-described circumstances, nanoimprint lithography, which is a method of pressing a mold having a predetermined pattern against a curable film formed on a substrate so that the pattern of the mold is transferred to the curable film, is expected as a fine pattern forming method for a semiconductor from the viewpoint of the productivity.

In the nanoimprint lithography, a photocurable composition containing a photocurable compound that is cured by light (ultraviolet rays or electron beams) is used. In such a case, a transfer pattern (structure) is obtained by pressing a mold having a predetermined pattern against a curable film containing a photocurable compound, irradiating the curable film with light to cure the photocurable compound, and peeling the mold off from the cured film.

In recent years, the application of nanoimprint lithography has been examined for enhancing the functionality of 3D sensors for autonomous driving and AR waveguides for AR (augmented reality) glasses. In 3D sensors and AR glasses, it is required to increase the refractive index of a permanent film material constituting a part of the device. It is known to add metal oxide nanoparticles as one means for increasing the refractive index of a nanoimprint material.

The photocurable composition used for nanoimprint lithography is required to have properties such as coatability in a case where a substrate is coated with the composition through spin coating or the like, and curability in a case where the composition is heated or exposed. In a case where the coatability thereof on the substrate is poor, the film thickness of the photocurable composition applied onto the substrate is uneven, and the pattern transferability is likely to be degraded in a case where the mold is pressed against the curable film. Further, the curability is an important property for maintaining the pattern formed by pressing the mold to have desired dimensions.

Further, the photocurable composition is also required to have satisfactory mold releasability in a case where the mold is peeled off from the cured film. For example, Japanese Unexamined Patent Application, First Publication No. 2016-207685 describes a nanoimprint composition having improved mold releasability by being blended with a fluorine-containing polymer compound.

### SUMMARY OF THE INVENTION

In a case where a line and space pattern with a small line width is intended to be formed for further miniaturization of wiring, there is a problem in that the filling property with respect to the mold is degraded. In a case where the particle diameter of the metal oxide nanoparticles is decreased, the mold filling property is enhanced, but the refractive index is decreased. Therefore, in formation of the line and space pattern having a small line width, it is required to maintain a high refractive index and improve the filling property with respect to the mold.

The present invention has been made in consideration of the above-described circumstances, and an object thereof is to provide a pattern forming method and a method of producing a curable composition, in which the filling property is satisfactory even in a case where the line width of a line and space pattern is small.

### Solution to Problem

In order to solve the above-described problems, the present invention has adopted the following configurations.

That is, according to a first aspect of the present invention, there is provided a pattern forming method including: forming a curable film using a curable composition that contains metal oxide nanoparticles, on a substrate; a step of pressing a mold having a line and space pattern against the curable film to transfer the line and space pattern to the curable film; curing the curable film to which the line and space pattern has been transferred while pressing the mold against the curable film, to form a cured film; and peeling the mold off from the cured film to form a line and space pattern on the substrate, in which a line width x of the line and space pattern formed on the substrate in a base portion and a volume average primary particle diameter φ of the metal oxide nanoparticles satisfy an expression of 0.03x<φ<0.08x, and an expression of x≤500 nm.

According to a second aspect of the present invention, there is provided a method of producing a curable composition for forming a line and space pattern on a substrate, the method including: selecting metal oxide nanoparticles having a volume average primary particle diameter φ which satisfies an expression of 0.03x<φ<0.08x with respect to a line width x of the line and space pattern in a base portion; and a preparing a curable composition containing the metal oxide nanoparticles, in which an expression of x≤500 nm is satisfied.

### Advantageous Effects of Invention

According to the present invention, it is possible to provide a pattern forming method and a method of producing a curable composition, in which the filling property is satisfactory even in a case where the line width of a line and space pattern is small.

### BRIEF DESCRIPTION OF THE DRAWINGS

FIG. 1A is a schematic diagram showing one step of an embodiment of a pattern forming method.

FIG. 1B is a schematic diagram showing one step of an embodiment of a pattern forming method.

FIG. 1C is a schematic diagram showing one step of an embodiment of a pattern forming method.

FIG. 1D is a schematic diagram showing one step of an embodiment of a pattern forming method.

FIG. 2A is a schematic view showing an example of a line and space pattern formed by the pattern forming method. FIG. 2A shows a rectangular pattern.

FIG. 2B is a schematic view showing an example of a line and space pattern formed by the pattern forming method. FIG. 2B shows a slant pattern.

FIG. 3 is a graph showing a relationship between a value (φ/x) of the ratio of a volume average primary particle diameter (φ) of metal oxide nanoparticles to the line width (x) of a line and space pattern formed by the pattern forming method and the filling property.

### DETAILED DESCRIPTION OF THE INVENTION

In the present description and the scope of the present patent claims, the term “aliphatic” is a relative concept used in relation to the term “aromatic”, and defines a group or compound that has no aromaticity.

The term “alkyl group” includes a linear, branched chain, or cyclic monovalent saturated hydrocarbon group unless otherwise specified. The same applies to the alkyl group in an alkoxy group.

The “(meth)acrylate” indicates at least one of acrylate and methacrylate.

The expression “may have a substituent” includes both a case where a hydrogen atom (—H) is substituted with a monovalent group and a case where a methylene (—CH₂—) group is substituted with a divalent group.

The term “light exposure” is a general concept for irradiation with radiation.

(Pattern Forming Method)

A pattern forming method according to a first embodiment of the present invention includes a step of forming a curable film using a curable composition that contains metal oxide nanoparticles, on a substrate (hereinafter, also referred to as “step (i)”), a step of pressing a mold having a line and space pattern against the curable film to transfer the line and space pattern to the curable film (hereinafter, also referred to as “step (ii)”), a step of curing the curable film to which the line and space pattern has been transferred while pressing the mold against the curable film, to form a cured film (hereinafter, also referred to as “step (iii)”), and a step of peeling the mold off from the cured film to form the line and space pattern on the substrate (hereinafter, also referred to as “step (iv)”. A line width x of the line and space pattern formed on the substrate in a base portion and a volume average primary particle diameter φ of the metal oxide nanoparticles satisfy an expression of 0.03x<φ<0.08x and an expression of x≤500 nm.

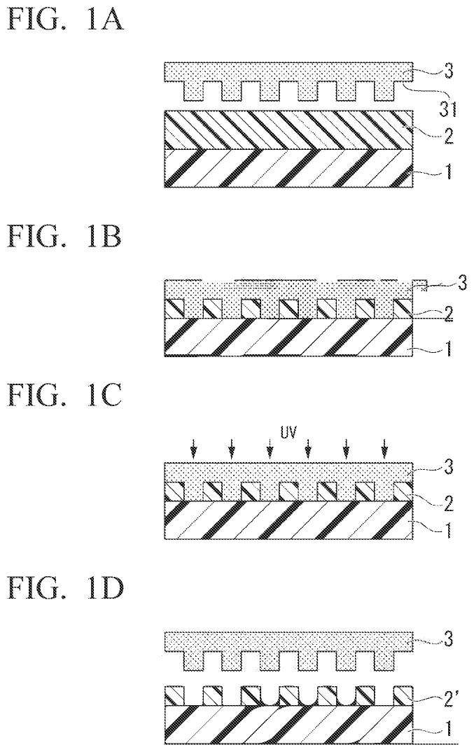

FIGS. 1A to 1D are schematic step views showing the embodiment of the pattern forming method.

[Step (i)]

In the step (i), a curable film is formed on the substrate by using a curable composition containing metal oxide nanoparticles.

As shown in FIG. 1A, a substrate 1 is coated with a curable composition containing metal oxide nanoparticles to form a curable film 2. In FIG. 1A, a mold 3 is disposed above the curable film 2.

The substrate 1 can be selected depending on various applications, and examples thereof include a substrate for an electronic component and a substrate on which a predetermined wiring pattern is formed. Specific examples thereof include a substrate made of a metal such as silicon, silicon nitride, copper, chromium, iron, or aluminum, and a glass substrate. Examples of the material of the wiring pattern include copper, aluminum, nickel, and gold.

Further, the shape of the substrate 1 is not particularly limited and may be a plate shape or a roll shape. Further, as the substrate 1, a light-transmitting or non-light-transmitting substrate can be selected depending on the combination with the mold and the like.

Examples of the method of coating the substrate 1 with the curable composition include a spin coating method, a spray method, an ink jet method, a roll coating method, and a rotary coating method. Since the curable film 2 functions as a mask in an etching step for the substrate 1 which may be subsequently performed, it is preferable that the curable film 2 has a uniform film thickness in a case where the substrate 1 is coated with the curable film 2. From this viewpoint, the spin coating method is suitable in a case where the substrate 1 is coated with the curable composition.

The film thickness of the curable film 2 may be appropriately selected depending on the applications thereof, and may be, for example, approximately in a range of 0.05 to 2 μm.

[Step (ii)]

In the step (ii), a mold having a line and space pattern is pressed against the curable film to transfer the line and space pattern to the curable film.

As shown in FIG. 1B, the mold 3 having a fine line and space pattern on the surface is pressed against the substrate 1 on which the curable film 2 has been formed such that the mold 3 faces the curable film 2. In this manner, the curable film 2 is deformed according to the uneven structure (line and space pattern structure) of the mold 3.

The pressure against the curable film 2 during the pressing of the mold 3 is preferably 10 MPa or less, more preferably 5 MPa or less, and particularly preferably 1 MPa or less.

The curable composition positioned on a convex portion (line) of the mold 3 is easily pushed away to a side of a concave portion (space) of the mold 3 by pressing the mold 3 against the curable film 2, and an uneven structure (line and space pattern structure) of the mold 3 is transferred to the curable film 2.

The line and space pattern of the mold 3 can be formed according to the desired processing accuracy by, for example, photolithography or an electron beam drawing method.

A light-transmitting mold is preferable as the mold 3. The material of the light-transmitting mold is not particularly limited, but may be any material having predetermined strength and durability. Specific examples thereof include a phototransparent resin film such as glass, quartz, polymethyl methacrylate, or a polycarbonate resin, a transparent metal vapor deposition film, a flexible film such as polydimethylsiloxane, a photocurable film, and a metal film.

[Step (iii)]

In the step (iii), the curable film to which the line and space pattern has been transferred is cured while the mold is pressed against the curable film to form a cured film.

As shown in FIG. 1C, the curable film 2 to which the line and space pattern has been transferred is cured in a state where the mold 3 is pressed against the curable film 2. In a case where the curable film 2 is a photocurable film, the curable film 2 can be cured upon exposure. Specifically, the curable film 2 is irradiated with electromagnetic waves such as ultraviolet rays (UV). The curable film 2 is cured upon exposure in the state where the mold 3 is pressed, and thus a cured film (cured pattern) to which the uneven pattern of the mold 3 has been transferred is formed. In a case where the curable film 2 is a photocurable film, the mold 3 in FIG. 1C has transparency to electromagnetic waves. The photocurable film can be formed by using the photocurable composition as the curable composition in the step (i).

In the case where the curable film 2 is a photocurable film, the light used to cure the curable film 2 is not particularly limited, and examples thereof include light or radiation having a wavelength in a region of high-energy ionizing radiation, near ultraviolet rays, far ultraviolet rays, visible rays, or infrared rays. For example, an i-line and a g-line of a mercury lamp, broad light of an ultra-high pressure mercury lamp, and an LED can also be suitably used. As the light, monochrome light may be used, or light having a plurality of different wavelengths (mixed light) may be used.

In a case where the curable film 2 is a thermosetting film, the curable film 2 can be cured by being heated. The thermosetting film can be formed by using the thermosetting composition as the curable composition in the step (i).

[Step (iv)]

In the step (iv), the mold is peeled off from the cured film to form a line and space pattern on the substrate.

As shown in FIG. 1D the mold 3 is peeled off from the cured film. In this manner, a line and space pattern 2′ (cured pattern) consisting of the cured film to which the line and space pattern has been transferred is patterned on the substrate 1.

In the present embodiment, a surface 31 of the mold 3 which is brought into contact with the curable film 2 may be coated with a release agent (FIG. 1A). In this manner, the releasability of the mold from the cured film can be improved.

Examples of the release agent here include a silicon-based release agent, a fluorine-based release agent, a polyethylene-based release agent, a polypropylene-based release agent, a paraffin-based release agent, a montan-based release agent, and a carnauba-based release agent. Among these, a fluorine-based release agent is preferable. For example, a commercially available coating type release agent such as OPTOOL DSX (manufactured by Daikin Industries, Ltd.) can be suitably used. The release agent may be used alone or a combination of two or more kinds thereof may be used.

The pattern forming method according to the present embodiment may further include other steps (optional steps) in addition to the steps (i) to (iv).

<Curable Composition>

The curable composition used in the pattern forming method according to the present embodiment contains metal oxide nanoparticles (hereinafter, also referred to as “X component”).

<<Component (X)>>

A component (X) is a metal oxide nanoparticle.

The term “nanoparticles” denotes particles having a volume average primary particle diameter in nanometer order (less than 1000 nm). The metal oxide nanoparticles denote metal oxide particles having a volume average primary particle diameter in nanometer order.

The volume average primary particle diameter φ of the component (X) is preferably 100 nm or less. The volume average primary particle diameter φ of the component (X) is preferably 0.1 nm or greater, more preferably 1 nm or greater, still more preferably 5 nm or greater, and particularly preferably 10 nm or greater. In a case where the volume average primary particle diameter φ thereof is greater than or equal to the above-described preferable lower limit, a high refractive index is likely to be maintained. The volume average primary particle diameter φ of the component (X) is preferably 60 nm or less, more preferably 50 nm or less, still more preferably 45 nm or less, and particularly preferably 40 nm or less. In a case where the volume average primary particle diameter φ thereof is less than or equal to the above-described preferable upper limit, the filling property is likely to be satisfactorily maintained. The volume average primary particle diameter φ thereof is preferably in a range of 0.1 to 100 nm, more preferably in a range of 5 to 60 nm, still more preferably in a range of 5 to 50 nm, and particularly preferably in a range of 10 to 40 nm. The metal oxide nanoparticles are satisfactorily dispersed in the curable composition by setting the volume average primary particle diameter of the metal nanoparticles of the component (X) to be in the above-described preferable range. The volume average primary particle diameter is a value measured by a dynamic light scattering method.

As the component (X), commercially available metal oxide nanoparticles can be used. Examples of the metal oxide include oxide particles such as titanium (Ti), zirconium (Zr), aluminum (Al), silicon (Si), zinc (Zn), and magnesium (Mg). Among these, from the viewpoint of the refractive index, titania (TiO₂) nanoparticles or zirconia (ZrO₂) nanoparticles are preferable, and titania (TiO₂) nanoparticles are more preferable as the component (X).

In the present embodiment, commercially available products of metal oxide nanoparticles can be used as the component (X).

Examples of commercially available titania nanoparticles include TTO Series (TTO-51 (A), TTO-51 (C), and the like), TTO-S, and V Series (TTO-S-1, TTO-S-2, TTO-V-3, and the like) (all manufactured by Ishihara Sangyo Kaisha, Ltd.), Titania Sol LDB-014-35 (manufactured by Ishihara Sangyo Kaisha, Ltd.), MT Series (MT-01, MT-05, MT-100SA, MT-500SA, and the like) (all manufactured by Tayca Corporation), ELECOM Series (manufactured by JGC C&C), and STR-100A-LP and the like (manufactured by Sakai Chemical Industry Co., Ltd.).

Examples of commercially available zirconia nanoparticles include UEP (manufactured by Daiichi Kisenso Kagaku-Kogyo Co., Ltd.), PCS (manufactured by Nippon Denko Co., Ltd.), JS-01, JS-03, JS-04 (manufactured by Nippon Denko Co., Ltd.), and UEP-100 (manufactured by Daiichi Kisenso Kagaku-Kogyo Co., Ltd.).

In the curable composition according to the present embodiment, the component (X) may be used alone or a combination of two or more kinds thereof may be used.

The amount of the component (X) in the curable composition according to the present embodiment can be set to be in a range of 10 to 99 parts by mass with respect to a total of 100 parts by mass of the component (X) and the component (B) described below. The amount of the component (X) in the curable composition according to the present embodiment is preferably in a range of 60 to 90 parts by mass, more preferably in a range of 60 to 85 parts by mass, still more preferably in a range of 60 to 80 parts by mass, and particularly preferably in a range of 60 to 75 parts by mass with respect to a total of 100 parts by mass of the component (X) and the component (B) described below.

In a case where the amount of the component (X) is greater than or equal to the lower limit of the above-described preferable range, the optical properties of the cured film formed by using the curable composition are further enhanced. Further, in a case where the amount of the component (X) is less than or equal to the upper limit of the above-described preferable range, the filling property of the curable composition into the mold is enhanced.

<<Optional Components>>

It is preferable that the curable composition also contains a polymerizable compound containing a polymerizable functional group (hereinafter, also referred to as “component (B)”) and a polymerization initiator (hereinafter, also referred to as “component (C)”) in addition to the component (X).

Component (B)

The component (B) is a polymerizable compound containing a polymerizable functional group.

The term “polymerizable functional group” denotes a group which is capable of polymerizing compounds through radical polymerization or the like and has multiple bonds between carbon atoms such as an ethylenic double bond.

Examples of the polymerizable functional group include a vinyl group, an allyl group, an acryloyl group, a methacryloyl group, a fluorovinyl group, a difluorovinyl group, a trifluorovinyl group, a difluorotrifluoromethylvinyl group, a trifluoroallyl group, a perfluoroallyl group, a trifluoromethylacryloyl group, a nonylfluorobutylacryloyl group, a vinyl ether group, a fluorine-containing vinyl ether group, an allyl ether group, a fluorine-containing allyl ether group, a styryl group, a vinylnaphthyl group, a fluorine-containing styryl group, a fluorine-containing vinylnaphthyl group, a norbornyl group, a fluorine-containing norbornyl group, and a silyl group. Among these, a vinyl group, an allyl group, an acryloyl group, or a methacryloyl group is preferable, and an acryloyl group or a methacryloyl group is more preferable.

Examples of the polymerizable compound (monofunctional monomer) containing one polymerizable functional group include a (meth)acrylate having an aliphatic polycyclic structure (hereinafter, referred to as a “component (B1)”) such as isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, or tricyclodecanyl (meth)acrylate; a (meth)acrylate having an aliphatic monocyclic structure such as dicyclopentanyl (meth)acrylate, dicyclopentenyl (meth)acrylate, cyclohexyl (meth)acrylate, 4-butylcyclohexyl (meth)acrylate, or acryloylmorpholin; a (meth)acrylate having a chain structure such as 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth) acrylate, or isostearyl (meth) acrylate; a (meth)acrylate having an aromatic ring structure (hereinafter, referred to as a component (B2)″) such as benzyl (meth)acrylate, phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, EO-modified p-cumylphenol (meth)acrylate, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, or polyoxyethylene nonylphenyl ether (meth)acrylate; tetrahydrofurfuryl (meth)acrylate, butoxyethyl (meth)acrylate, ethoxydiethylene glycol (meth)acrylate, polyethylene glycol mono(meth)acrylate, polypropylene glycol mono(meth)acrylate, methoxyethylene glycol(meth)acrylate, ethoxyethyl (meth)acrylate, methoxypolyethylene glycol (meth)acrylate, methoxypolypropylene glycol (meth)acrylate; diacetone (meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, N,N-dimethylaminopropyl (meth)acrylamide; and an one-terminal methacrylsiloxane monomer.

Examples of the commercially available product of the monofunctional monomer include ARONIX M101, M102, M110, M111, M113, M117, M5700, TO-1317, M120, M150, and M156 (all manufactured by Toagosei Co., Ltd.); MEDOL10, MIBDOL10, CHDOL10, MMDOL30, MEDOL30, MIBDOL30, CHDOL30, LA, IBXA, 2-MTA, HPA, VISCOAT #150, #155, #158, #190, #192, #193, #220, #2000, #2100, and #2150 (all manufactured by Osaka Organic Chemical Industry Ltd.); light acrylate BO-A, EC-A, DMP-A, THF-A, HOP-A, HOA-MPE, HOA-MPL, HOA (N), PO-A, P-200A, NP-4EA, NP-BEA, IB-XA, and Epoxy Ester M-600A (all manufactured by Kyoeisha Chemical Co., Ltd.); KAYARAD TC110S, R-564, and R-128H (all manufactured by Nippon Kayaku Co., Ltd.); NK ester AMP-10G and AMP-20G (both manufactured by Shin-Nakamura Chemical Industry Co., Ltd.); FA-511A, FA-512A, FA-513A, and FA-BZA (all manufactured by Hitachi Chemical Co., Ltd.); PHE, CEA, PHE-2, PHE-4, BR-31, BR-31M, and BR-32 (all manufactured by DKS Co., Ltd.); VP (manufactured by BASF SE); ACMO, DMAA, and DMAPAA (all manufactured by Kohjin); and X-22-2404 (manufactured by Shin-Etsu Chemical Co., Ltd.).

Examples of the polymerizable compound containing two polymerizable functional groups (bifunctional monomer) include trimethylolpropane di(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, and bis(hydroxylmethyl) tricyclodecane di(meth)acrylate.

Examples of commercially available products of the bifunctional monomer include light acrylates 3EG-A, 4EG-A, 9EG-A, NP-A, DCP-A, BP-4EAL, and BP-4PA (all manufactured by Kyoeisha Chemical Co., Ltd.), and ARONIX M-208, M-211B, M-215, M-220, and M-240 (all manufactured by Toagosei Co., Ltd.).

Examples of the polymerizable compound containing three or more polymerizable functional groups include a polymerizable siloxane compound, a polymerizable silsesquioxane compound, and a polyfunctional monomer containing three or more polymerizable functional groups.

Examples of the polymerizable siloxane compound include a compound containing an alkoxysilyl group and a polymerizable functional group in a molecule.

Examples of commercially available products of the polymerizable siloxane compound include “KR-513”, “X-40-9296”, “KR-511”, “X-12-1048”, and “X-12-1050” (product names, all manufactured by Shin-Etsu Chemical Co., Ltd.).

Examples of the polymerizable silsesquioxane compound include a compound which has a main chain skeleton consisting of a Si—O bond and is represented by the following chemical formula: [(RSiO_{3/2})ₙ] (in the formula, R represents an organic group and n represents a natural number).

R represents a monovalent organic group, and examples of the monovalent organic group include a monovalent hydrocarbon group which may have a substituent. Examples of the hydrocarbon group include an aliphatic hydrocarbon group and an aromatic hydrocarbon group. Examples of the aliphatic hydrocarbon group include an alkyl group having 1 to 20 carbon atoms such as a methyl group, an ethyl group, an n-propyl group, an isopropyl group, an n-butyl group, a sec-butyl group, a tert-butyl group, a pentyl group, a hexyl group, a heptyl group, a 2-ethylhexyl group, an octyl group, a nonyl group, a decyl group, an undecyl group, or a dodecyl group. Among these, an alkyl group having 1 to 12 carbon atoms is preferable.

Examples of the aromatic hydrocarbon group include an aromatic hydrocarbon group having 6 to 20 carbon atoms such as a phenyl group, a naphthyl group, a benzyl group, a tolyl group, or a styryl group.

Examples of the substituent that a monovalent hydrocarbon group may have include a (meth)acryloyl group, a hydroxy group, a sulfanyl group, a carboxy group, an isocyanate group, an amino group, and a ureido group. Further, —CH₂— contained in the monovalent hydrocarbon group may be replaced with —O—, —S—, a carbonyl group, or the like.

Here, the polymerizable silsesquioxane compound contains three or more polymerizable functional groups. Examples of the polymerizable functional group here include a vinyl group, an allyl group, a methacryloyl group, and an acryloyl group.

The compound represented by the chemical formula: [(RSiO_{3/2})ₙ] may be of a basket type, a ladder type, or a random type. The basket-type silsesquioxane compound may be of a complete basket type or an incomplete basket type in which a part of the basket is open.

Examples of commercially available products of the polymerizable silsesquioxane compound include “MAC-SQ LP-35”, “MAC-SQ TM-100”, “MAC-SQ SI-20”, and “MAC-SQ HDM” (all product names, manufactured by Toagosei Co., Ltd.).

Examples of the polyfunctional monomer containing three or more polymerizable functional groups include a trifunctional monomer such as ethoxylated (3) trimethylolpropane triacrylate, ethoxylated (3) trimethylolpropane trimethacrylate, ethoxylated (6) trimethylolpropane triacrylate, ethoxylated (9) trimethylolpropane triacrylate, ethoxylated (15) trimethylolpropane triacrylate, ethoxylated (20) trimethylolpropane triacrylate, pentaerythritol triacrylate, pentaerythritol trimethacrylate, propoxylated (3) glyceryl triacrylate, propoxylated (3) glyceryl triacrylate, propoxylated (5.5) glyceryl triacrylate, propoxylated (3) trimethylolpropane triacrylate, propoxylated (6) trimethylolpropane triacrylate, trimethylolpropane triacrylate, trimethylolpropane trimethacrylate, tris-(2-hydroxyethyl)-isocyanurate triacrylate, tris-(2-hydroxyethyl)-isocyanurate trimethacrylate, ε-caprolactone-modified tris-(2-acryloxyethyl) isocyanurate, EO-modified trimethylolpropane φ(meth)acrylate, PO-modified trimethylolpropane φ(meth)acrylate, or EO,PO-modified trimethylolpropane φ(meth)acrylate, a tetrafunctional monomer such as ditrimethylolpropane tetraacrylate, ethoxylated (4) pentaerythritol tetraacrylate, or pentaerythritol tetra(meth)acrylate, and a pentafunctional or higher functional monomer such as dipentaerythritol pentaacrylate or dipentaerythritol hexaacrylate.

Examples of the commercially available product of the polyfunctional monomer include “A-9300-1CL”, “AD-TMP”, “A-9550”, and “A-DPH” (all manufactured by Shin-Nakamura Chemical Industry Co., Ltd.), “KAYARAD DPHA” (product name, manufactured by Nippon Kayaku Co., Ltd.), and “Light Acrylate TMP-A” (product name, manufactured by Kyoeisha Chemical Co., Ltd.).

The curable composition may contain only one or a combination of two or more components (B).

The amount of the component (B) can be set to be in a range of 5 to 80 parts by mass with respect to a total of 100 parts by mass of the component (X), the component (B), and the component (C) described below. The amount of the component (B) is preferably in a range of 10 to 40 parts by mass, more preferably in a range of 15 to 40 parts by mass, still more preferably in a range of 20 to 40 parts by mass, and particularly preferably in a range of 25 to 40 parts by mass with respect to a total of 100 parts by mass of the component (X), the component (B), and the component (C) described below.

In a case where the amount of the component (B) is greater than or equal to the lower limit of the above-described preferable range, the curability and fluidity of the cured film formed by using the curable composition are enhanced. Further, in a case where the amount of the component (B) is less than or equal to the upper limit of the above-described preferable range, the dispersibility of the component (X) in the curable composition is enhanced.
Component (C)

The component (C) is a polymerization initiator.

In a case where the curable composition is a photocurable composition, the component (C) is a photopolymerization initiator. As the component (C), a compound that initiates polymerization of the component (B) upon exposure or promotes the polymerization is used. It is preferable that the component (C) is a photoradical polymerization agent.

Examples of the photoradical polymerization agent include 1-hydroxycyclohexylphenyl ketone, 2-hydroxy-2-methyl-1-phenylpropan-1-one, 1-[4-(2-hydroxyethoxy)phenyl]-2-hydroxy-2-methyl-1-propan-1-one, 1-(4-isopropylphenyl)-2-hydroxy-2-methylpropan-1-one, 1-(4-dodecylphenyl)-2-hydroxy-2-methylpropan-1-one, 2,2-dimethoxy-1,2-diphenylethan-1-one, bis(4-dimethylaminophenyl)ketone, 2-methyl-1-(4-methylthiophenyl)-2-morpholinopropan-1-one, 2-benzyl-2-dimethylamino-1-(4-morpholinophenyl)-butanon-1, ethanone-1-[9-ethyl-6-(2-methylbenzoyl)-9H-carbazol-3-yl]-1-(o-acetyloxime), bis(2,4,6-trimethylbenzoyl)-phenylphosphine oxide, 4-benzoyl-4′-methyldimethylsulfide, 4-dimethylaminobenzoic acid, methyl 4-dimethylaminobenzoate, ethyl 4-dimethylaminobenzoate, butyl 4-dimethylaminobenzoate, 4-dimethylamino-2-ethylhexylbenzoic acid, 4-dimethylamino-2-isoamylbenzoic acid, benzyl-o-methoxyethyl acetal, benzyl dimethyl ketal, 1-phenyl-1,2-propanedion-2-(o-ethoxycarbonyl)oxime, methyl o-benzoyl benzoate, 2,4-diethylthioxanthone, 2-chlorothioxanthone, 2,4-dimethylthioxanthone, 1-chloro-4-propoxythioxanthone, thioxanthene, 2-chlorothioxanthene, 2,4-diethylthioxanthene, 2-methylthioxanthene, 2-isopropylthioxanthene, 2-ethylanthraquinone, octamethyl anthraquinone, 1,2-benzanthraquinone, 2,3-diphenylanthraquinone, azobisisobutyronitrile, benzoyl peroxide, cumeme peroxide, 2-mercaptobenzoimidal, 2-mercaptobenzoxazole, 2-mercaptobenzothiazole, a 2-(o-chlorophenyl)-4,5-di(m-methoxyphenyl)-imidazolyl dimer, benzophenone, 2-chlorobenzophenone, p,p′-bisdimethylaminobenzophenone, 4,4′-bisdiethylaminobenzophenone, 4,4′-dichlorobenzophenone, 3,3-dimethyl-4-methoxybenzophenone, benzoyl, benzoin, benzoin methyl ether, benzoin ethyl ether, benzoin isopropyl ether, benzoin-n-butyl ether, benzoin isobutyl ether, benzoin butyl ether, acetophenone, 2,2-diethoxyacetophenone, p-dimethylacetophenone, p-dimethylaminopropiophenone, dichloroacetophenone, trichloroacetophenone, p-tert-butylacetophenone, p-dimethylaminoacetophenone, p-tert-butyltrichloroacetophenone, p-tert-butyldichloroacetophenone, α,α-dichloro-4-phenoxyacetophenone, 2,2-dimethoxy-2-phenylacetophenone, thioxanthone, 2-methylthioxanthone, 2-isopropylthioxanthone, dibenzosuberone, pentyl-4-dimethylaminobenzoate, 9-phenylacridine, 1,7-bis-(9-acridinyl)heptane, 1,5-bis-(9-acridinyl)pentane, 1,3-bis-(9-acridinyl)propane, p-methoxytriazine, 2,4,6-tris(trichloromethyl)-s-triazine, 2-methyl-4,6-bis(trichloromethyl)-s-triazine, 2-[2-(5-methylfuran-2-yl)ethenyl]-4,6-bis(trichloromethyl)-s-triazine, 2-[2-(fran-2-yl)ethenyl]-4,6-bis (trichloromethyl)-s-triazine, 2-[2-(4-diethylamino-2-methylphenyl)ethenyl]-4,6-bis(trichloromethyl)-s-triazine, 2-[2-(3,4-dimethoxyphenyl)ethenyl]-4,6-bis(trichloromethyl)-s-triazine, 2-(4-methoxyphenyl)-4,6-bis(trichloromethyl)-s-triazine, 2-(4-ethoxystyryl)-4,6-bis(trichloromethyl)-s-triazine, 2-(4-n-butoxyphenyl)-4,6-bis(trichloromethyl)-s-triazine, 2,4-bis-trichloromethyl-6-(3-bromo-4-methoxy)phenyl-s-triazine, 2,4-bis-trichloromethyl-6-(2-bromo-4-methoxy)phenyl-s-triazine, 2,4-bis-trichloromethyl-6-(3-bromo-4-methoxy)styrylphenyl-s-triazine, 2,4-bis-trichloromethyl-6-(2-bromo-4-methoxy)styrylphenyl-s-triazine; ketone peroxides such as methyl ethyl ketone peroxide, methyl isobutyl ketone peroxide, and cyclohexanone peroxide; diacyl peroxides such as isobutylyl peroxide and bis(3,5,5-trimethylhexanoyl)peroxide; hydroperoxides such as p-menthanehydroperoxide and 1,1,3,3-tetramethylbutylhydroperoxide; dialkyl peroxides such as 2,5-dimethyl-2,5-bis(t-butylperoxy)hexane; peroxy ketals such as 1,1-bis(t-butylperoxy)-3,3,5-trimethylcyclohexane; peroxy esters such as t-butylperoxyneodecanoate and 1,1,3,3-tetramethylperoxyneodecanoate; peroxydicarbonates such as di-n-propyl peroxydicarbonate and diisopropyl peroxydicarbonate; and azo compounds such as azobisisobutyronitrile, 2,2′-azobis(2,4-dimethylvaleronitrile), and 2,2′-azobisisobutyrate.

Among these, 1-hydroxycyclohexylphenyl ketone, 2-methyl-1-(4-methylthiophenyl)-2-morpholinopropan-1-one, 2-benzyl-2-dimethylamino-1-(4-morpholinophenyl)-butanone-1, bis(2,4,6-trimethylbenzoyl)-phenylphosphine oxide, and 2,2-dimethoxy-2-phenylacetophenone are preferable.

As the photoradical polymerization agent, a commercially available product can be obtained and used.

Examples of the commercially available product of the photoradical polymerization agent include “IRGACURE 907” (product name, manufactured by BASF SE), “IRGACURE 369” (product name, manufactured by BASF SE), “IRGACURE 819” (product name, manufactured by BASF SE), and “Omnirad 184”, “Omnirad 651”, and “Omnirad 819” (all product name, manufactured by IGM Resins B. V.).

In a case where the curable composition is a thermosetting composition, the component (C) is a thermal polymerization initiator. Examples of the thermal polymerization initiator include a peroxide and an azo-based polymerization initiator.

Examples of the peroxide include ketone peroxide, peroxyketal, hydroperoxide, dialkyl peroxide, and peroxy ester. Specific examples of such a peroxide include acetyl peroxide, dicumyl peroxide, tert-butyl peroxide, t-butylcumyl peroxide, propionyl peroxide, benzoyl peroxide (BPO), 2-chlorobenzoyl peroxide, 3-chlorobenzoyl peroxide, 4-chlorobenzoyl peroxide, 2,4-dichlorobenzoyl peroxide, 4-bromomethylbenzoyl peroxide, lauroyl peroxide, potassium persulfate, diisopropyl peroxycarbonate, tetralin hydroperoxide, 1-phenyl-2-methylpropyl-1-hydroperoxide, tert-butyl-pertriphenyl acetate, tert-butylhydroperoxide, tert-butyl performate, tert-butyl peracetate, tert-butyl perbenzoate, tert-butyl-perphenylacetate, tert-butyl per-4-methoyxacetate, and tert-butyl per-N-(3-toluyl)carbamate.

Examples of the azo-based polymerization initiator include 2,2′-azobispropane, 2,2′-dichloro-2,2′-azobispropane, 1,1′-azo(methylethyl) diacetate, 2,2′-azobis(2-amidinopropane) hydrochloride, 2,2′-azobis(2-aminopropane) nitrate, 2,2′-azobisisobutane, 2,2′-azobisisobutylamide, 2,2′-azobisisobutyronitrile, methyl 2,2′-azobis-2-methylpropionate, 2,2′-dichloro-2,2′-azobisbutane, 2,2′-azobis-2-methylbutyronitrile, dimethyl 2,2′-azobisisobutyrate, 1,1′-azobis(sodium 1-methylbutyronitrile-3-sulfonate), 2-(4-methylphenylazo)-2-methylmalonodinitrile 4,4′-azobis-4-cyanovaleric acid, 3,5-dihydroxymethylphenylazo-2-allylmalonodinitrile, 2,2′-azobis-2-methylvaleronitrile, dimethyl 4,4′-azobis-4-cyanovalerate, 2,2′-azobis-2,4-dimethylvaleronitrile, 1,1′-azobiscyclohexanenitrile, 2,2′-azobis-2-propylbutyronitrile, 1,1′-azobiscyclohexanenitrile, 2,2′-azobis-2-propylbutyronitrile, 1,1′-azobis-1-chlorophenylethane, 1,1′-azobis-1-cyclohexanecarbonitrile, 1,1′-azobis-1-cycloheptanenitrile, 1,1′-azobis-1-phenylethane, 1,1′-azobiscumene, ethyl 4-nitrophenylazobenzylcyanoacetate, phenylazodiphenylmethane, phenylazotriphenylmethane, 4-nitrophenylazotriphenylmethane, 1,1′-azobis-1,2-diphenylethane, poly(bisphenol A-4,4′-azobis-4-cyanopentanoate), and poly(tetraethyleneglycol-2,2′-azobisisobutyrate).

The curable composition may contain only one or a combination of two or more components (C).

The amount of the component (C) in the curable composition is preferably in a range of 0.01 to 15 parts by mass, more preferably in a range of 0.1 to 10 parts by mass, and still more preferably in a range of 0.5 to 5 parts by mass with respect to a total of 100 parts by mass of the component (X), the component (B), and the component (C). In a case where the amount of the component (C) is in the above-described preferable range, the curability of the curable composition is enhanced.

The curable composition may contain other components in addition to the component (X), the component (B), and the component (C). Examples of the other components include solvents (component (S)) and miscible additives (such as a deterioration inhibitor, a release agent, a diluent, an antioxidant, a heat stabilizer, a flame retardant, a plasticizer, a surfactant, and other additives for improving the characteristics of the cured film).
Solvent: component (S)

The curable composition may contain a solvent (component (S)). The component (S) is used to dissolve or disperse and mix the component (X), the component (B), the component (C), and desired optional components.

Examples of the component (S) includes alcohols having a chain structure such as methanol, ethanol, n-propyl alcohol, isopropyl alcohol, n-pentyl alcohol, s-pentyl alcohol, t-pentyl alcohol, isopentyl alcohol, 2-methyl-1-propanol, 2-ethylbutanol, neopentyl alcohol, n-butanol, s-butanol, t-butanol, 1-propanol, n-hexanol, 2-heptanol, 3-heptanol, 2-methyl-1-butanol, 2-methyl-2-butanol, 4-methyl-2-pentanol, 1-butoxy-2-propanol, propylene glycol monopropyl ether, 5-methyl-1-hexanol, 6-methyl-2-heptanol, 1-octanol, 2-octanol, 3-octanol, 4-octanol, 2-ethyl-1-hexanol, and 2-(2-butoxyethoxy) ethanol; alcohols having a cyclic structure such as cyclopentanemethanol, 1-cyclopentylethanol, cyclohexanol, cyclohexanemethanol, cyclohexaneethanol, 1,2,3,6-tetrahydrobenzyl alcohol, exo-norborneol, 2-methylcyclohexanol, cycloheptanol, 3,5-dimethylcyclohexanol, benzyl alcohol, and terpineol; and compounds having an ester bond, such as ethylene glycol monoacetate, diethylene glycol monoacetate, propylene glycol monoacetate, and dipropylene glycol monoacetate; derivatives of polyhydric alcohols of compounds having an ether bond such as monoalkyl ether or monophenyl ether, such as monomethylether, monoethylether, monopropylether, or monobutylether of polyhydric alcohols or compounds having an ester bond [among these, propylene glycol monomethyl ether acetate (PGMEA) and propylene glycol monomethyl ether (PGME) are preferable].

The curable composition may contain only one or a combination of two or more components (S).

Among these, as the component (S), at least one selected from the group consisting of propylene glycol monomethyl ether acetate (PGMEA) and propylene glycol monomethyl ether (PGME) is preferable.

The amount of the component (S) to be used is not particularly limited and may be appropriately set according to the thickness of the coating film of the curable composition. For example, the amount of the component (S) to be used can be set to be in a range of approximately 100 to 500 parts by mass with respect to a total of 100 parts by mass of the component (X), the component (B), and the component (C).

Surfactant: component (E) The curable composition may contain a surfactant to adjust the coatability and the like.

Examples of the surfactant include a silicone-based surfactant and a fluorine-based surfactant. As the silicone-based surfactant, for example, BYK-077, BYK-085, BYK-300, BYK-301, BYK-302, BYK-306, BYK-307, BYK-310, BYK-320, BYK-322, BYK-323, BYK-325, BYK-330, BYK-331, BYK-333, BYK-335, BYK-341, BYK-344, BYK-345, BYK-346, BYK-348, BYK-354, BYK-355, BYK-356, BYK-358, BYK-361, BYK-370, BYK-371, BYK-375, BYK-380, and BYK-390 (all manufactured by BYK-Chemie GmbH) and the like can be used. As the fluorine-based surfactant, F-114, F-177, F-410, F-411, F-450, F-493, F-494, F-443, F-444, F-445, F-446, F-470, F-471, F-472SF, F-474, F-475, F-477, F-478, F-479, F-480SF, F-482, F-483, F-484, F-486, F-487, F-172D, MCF-350SF, TF-1025SF, TF-1117SF, TF-1026SF, TF-1128, TF-1127, TF-1129, TF-1126, TF-1130, TF-1116SF, TF-1131, TF-1132, TF-1027SF, TF-1441, and TF-1442 (all manufactured by DIC Corporation), and PolyFox Series PF-636, PF-6320, PF-656, and PF-6520 (all manufactured by Omnova Solutions Inc.) and the like can be used.

The curable composition may contain only one or a combination of two or more kinds of surfactants.

In a case where the curable composition contains a surfactant, the amount of the surfactant is preferably in a range of 0.01 to 3 parts by mass, more preferably in a range of 0.02 to 1 part by mass, and still more preferably in a range of 0.03 to 0.5 parts by mass with respect to a total of 100 parts by mass of the component (X) and the component (B).

In a case where the amount of the surfactant is in the above-described preferable range, the coatability of the curable composition is enhanced.

The cured film formed of the curable composition typically has a refractive index of preferably 1.70 or greater at a wavelength of 530 nm. In a case where a cured film having a high refractive index can be formed, the cured film can be suitably used for applications requiring a high refractive index such as 3D sensors and AR waveguides for AR (augmented reality) glasses. The refractive index of the cured film can be measured by a spectroscopic ellipsometer.

<Line and Space Pattern>

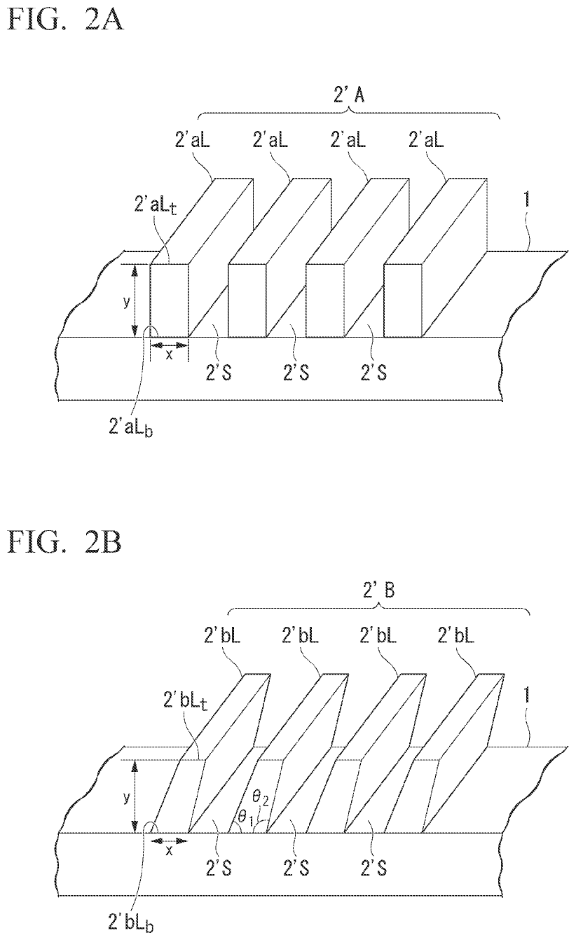

The pattern formed by the pattern forming method of the present embodiment is a line and space pattern. Here, “line and space pattern” is a pattern in which line-like convex portions (lines) and line-like concave portions (spaces) are alternately repeated (see FIGS. 2A and 2B).

The shape of the convex portion of the line and space pattern is not particularly limited. Examples of the shape of a vertical cross section of the convex portion include a square shape and a trapezoidal shape. It is preferable that the upper surface of the convex portion is substantially parallel to the surface of the substrate on which the pattern is formed.

FIG. 2A shows a rectangular pattern which is an example of the line and space pattern. Here, “rectangular pattern” is a line and space pattern in which the shape of a vertical cross section of the convex portion is a square shape (rectangular shape). As shown in FIG. 2A, convex portions 2′aL (line) and concave portions 2'S (space) are alternately repeated to form a rectangular pattern 2′A. The shape of the vertical cross section of the convex portion 2′aL in the rectangular pattern 2′A is a square shape. The surface on which a lower side 2′aL_{b} in a square shape formed by the vertical cross section of the convex portion 2′aL is formed is in contact with the substrate 1. The surface on which an upper side 2′aLₜ in a square shape formed by the vertical cross section of the convex portion 2′aL is formed forms the top portion of the convex portion 2′aL. The portion where the convex portion 2′aL is in contact with the substrate 1 is the base portion of the line and space pattern. The line width x of the line and space pattern in the base portion coincides with the length of the lower side 2′aL_{b} of the square, which is the shape of the vertical cross section of the convex portion 2′aL.

FIG. 2B shows a slant pattern which is an example of the line and space pattern. Here, “slant pattern” is a line and space pattern in which the shape of a vertical cross section of the convex portion is a trapezoidal shape. As shown in FIG. 2B, the convex portions 2′bL (lines) and the concave portions 2'S (spaces) are alternately repeated to form a slant pattern 2′B. The shape of the vertical cross section of the convex portion 2′bL in the slant pattern 2′B is a trapezoidal shape. The surface forming a trapezoidal lower bottom 2′bL_{b} formed by the vertical cross section of the convex portion 2′bL is in contact with the substrate 1. The surface forming a trapezoidal upper bottom 2′bLₜ formed by the vertical cross section of the convex portion 2′bL forms the top portion of the convex portion 2′bL. The portion where the convex portion 2′bL is in contact with the substrate 1 is the base portion of the line and space pattern. The line width x of the line and space pattern in the base portion coincides with the length of the trapezoidal lower bottom 2′bL_{b} in a trapezoidal shape which is the shape of the vertical cross section of the convex portion 2′bL.

It is preferable that the trapezoid which is the shape of the vertical cross section of the convex portion 2′bL is formed such that a first internal angle θ1 in the lower bottom 2′bL_{b} is less than 900 and a second internal angle θ₂ in the lower bottom 2′bL_{b} is greater than 90°. The first internal angle θ1 in the lower bottom 2′bL_{b} is preferably 45° or greater, more preferably 60° or greater, and still more preferably 70° or greater. The second internal angle θ₂ in the lower bottom 2′bL_{b} is preferably 135° or less, more preferably 120° or less, and still more preferably 110° or less.

In the trapezoid which is the shape of the vertical cross section of the convex portion 2′bL, it is preferable that the length of the lower bottom 2′bL_{b} is greater than the length of the upper bottom 2′bLₜ.

In the pattern forming method of the present embodiment, the line width x of the line and space pattern in the base portion, which is formed on the substrate and the volume average primary particle diameter φ of the metal oxide nanoparticles contained in the curable composition satisfy Expressions (1) and (2).

0.03x<φ<0.08x (1)

x≤500 nm (2)

In general, the filling property of the curable composition with respect to the mold is degraded as the line width x decreases. Further, the filling property of the curable composition with respect to the mold 3 is degraded as the volume average primary particle diameter p of the metal oxide nanoparticles increases. Further, the refractive index of the pattern is likely to decrease as the volume average primary particle diameter p of the metal oxide nanoparticles decreases. However, in a case where the line width x and the volume average primary particle diameter p of the metal oxide nanoparticles satisfy Expressions (1) and (2), the refractive index of the pattern is maintained to be high while the filling property of the curable composition with respect to the mold is maintained satisfactorily.

The volume average primary particle diameter p is preferably smaller than 0.07x, more preferably smaller than 0.06x, and still more preferably smaller than 0.055. The volume average primary particle diameter φ is preferably greater than 0.033x, more preferably 0.034x or greater, and still more preferably 0.035 or greater. In a case where the volume average primary particle diameter φ is in the above-described preferable range, the refractive index of the pattern is maintained to be high while the filling property of the curable composition with respect to the mold is maintained satisfactorily.

The line width x is preferably 100 nm or greater, more preferably 150 nm or greater, still more preferably 200 nm or greater, and particularly preferably 250 nm or greater. The line width x is preferably 450 nm or less and more preferably 400 nm or less. In a case where the line width is in the above-described preferable range, the refractive index is likely to be maintained to be high and the filling property is likely to be enhanced.

It is preferable that the line (convex portion) height y (see FIGS. 2A and 2B) and the line width x of the line and space pattern satisfy Expression (3). In a case where Expression (3) is satisfied, the aspect ratio of the pattern increases and thus the pattern shape is satisfactory. In a case where the aspect ratio of the pattern increases, the effect of improving the diffraction effect or improving etching resistance is expected.

y≥x (3)

In the pattern forming method of the present embodiment described above, the line width x of the line and space pattern and the volume average primary particle diameter φ of the metal oxide nanoparticles contained in the curable composition satisfy Expressions (1) and (2). In a case where a line and space pattern having a fine line width that satisfies Expression (2), the filling property of the curable composition with respect to the mold is problematic. However, in the pattern forming method of the present embodiment, the filling property of the curable composition with respect to the mold can be maintained satisfactorily by preparing the curable composition such that Expression (1) is satisfied.

Such a pattern forming method is useful as a pattern forming method of forming a fine pattern on a substrate using an imprint technology and is particularly suitable for imprint lithography. In particular, the pattern forming method exerts an advantageous effect in applications that require a high refractive index, such as 3D sensors for autonomous driving and AR waveguides for AR (augmented reality) glasses.

(Method of Producing Curable Composition)

A method of producing a curable composition according to a second embodiment of the present invention is a method of producing a curable composition for forming a line and space pattern on a substrate. The method of producing a curable composition according to the second embodiment includes a step of selecting metal oxide nanoparticles having a volume average primary particle diameter φ which satisfies an expression of 0.03x<φ<0.08x with respect to a line width x of the line and space pattern in a base portion (hereinafter, also denoted as “step (a)”), and a step of preparing a curable composition containing the metal oxide nanoparticles (hereinafter, also denoted as “step (b)”). The line width x satisfies an expression of x≤500 nm.

[Step (a)]

In the step (a), metal oxide nanoparticles having a volume average primary particle diameter φ which satisfies an expression of 0.03x<φ<0.08x with respect to the line width x of the line and space pattern in the base portion are selected.

Metal oxide nanoparticles having a volume average primary particle diameter φ which satisfies Expression (1) are selected according to the line width x of the line and space pattern formed by using the curable composition.

03x<φ<0.08x (1)

The metal oxide nanoparticles are not particularly limited as long as the metal oxide nanoparticles have a volume average primary particle diameter φ which satisfies Expression (1). Examples of the metal oxide nanoparticles are the same as those provided as exemplary examples of the component (X) above.

Examples of the line and space pattern formed by using the curable composition are the same as those described above. Specific examples thereof include a rectangular pattern and a slant pattern. The line width x in the line and space pattern satisfies Expression (2).

x<500 nm (2)

It is preferable that the line width x and the line (convex portion) height y of the line and space pattern satisfy Expression (3).

y≥x (3)

[Step (b)]

In the step (b), a curable composition containing the metal oxide nanoparticles is prepared.

The curable composition can be prepared by adding optional components to the metal oxide nanoparticles and mixing the mixture, as necessary. Examples of the optional components include the above-described component (B), component (C), component (S), and component (E).

It is preferable that the curable composition is prepared by adding the component (B) and the component (C) to the metal oxide nanoparticles and mixing the mixture. It is more preferable that the curable composition is prepared by dissolving or dispersing the metal oxide nanoparticles, the component (B), and the component (C) in the component (S) and mixing the mixture.

According to the method of producing a curable composition of the present embodiment, the metal oxide nanoparticles are selected according to the line width x of the line and space pattern formed by using the curable composition. Therefore, a curable composition having a satisfactory filling property with respect to the mold used for forming the line and space pattern can be obtained.

### EXAMPLES

Hereinafter, the present invention will be described in more detail with reference to examples, but the present invention is not limited to these examples.

<Preparation of Photocurable Composition>

Each curable composition of each example was prepared by blending the respective components listed in Table 1.

TABLE 1

| | | | | Photopoly- | |
|---|---|---|---|---|---|
| | Metal oxide | Polymerizable | | merization | |
| | nanoparticles | monomer | | initiator | Solvent |
| | Component | Component | | Component | Component |
| | (X) | (B) | | (C) | (S) |
| Composition | (X)-1 | (B)-1 | (B)-2 | (C)-1 | (S)-1 |
| 1 | [70] | [20] | [8] | [2] | [175] |
| Composition | (X)-2 | (B)-1 | (B)-2 | (C)-1 | (S)-1 |
| 2 | [70] | [20] | [8] | [3] | [175] |
| Composition | (X)-3 | (B)-1 | (B)-2 | (C)-1 | (S)-1 |
| 3 | [70] | [20] | [8] | [4] | [175] |
| Composition | (X)-4 | (B)-1 | (B)-2 | (C)-1 | (S)-1 |
| 4 | [70] | [20] | [8] | [5] | [175] |

In Table 1, each abbreviation has the following meaning. The numerical values in the parentheses are blending amounts (parts by mass).
Component (X) (metal oxide nanoparticles)

(X) −1: titania particles with a volume average primary particle diameter of 12 nm

(X) −2: titania particles with a volume average primary particle diameter of 15 nm

(X) −3: titania particles with a volume average primary particle diameter of 18 nm

(X) −4: titania particles with a volume average primary particle diameter of 42 nm
Component (B) (photopolymerizable compound)

(B)-1: dipentaerythritol hexaacrylate, product name “KAYARAD DPHA”, manufactured by Nippon Kayaku Co., Ltd.

(B)-2: polyethylene glycol (n≈4) diacrylate, product name “ARONIX (registered trademark) M-240”, manufactured by Toagosei Co., Ltd.
Component (C) (photoradical polymerization initiator)

(C)-1: 2-methyl-1-(4-methylthiophenyl)-2-morpholinopropan-1-one, product name “Omnirad Irgacure 907”, manufactured by IGM Resins B.V.
Component (S) (solvent)

(S)-1: propylene glycol monomethyl ether

[Pattern Formation]

A silicon substrate was spin-coated with the curable composition of each example such that the film thickness thereof was adjusted to 600 nm. Next, the composition was prebaked at 90° C. for 1 minute and transferred using an imprint device ST-200 (manufactured by Toshiba Machine Co., Ltd.) at a transfer pressure of 0.5 MPa and an exposure amount of 1 J/cm² for a transfer time of 30 seconds (in a vacuum atmosphere of 200 Pa). The used composition, the volume average primary particle diameter ((p) of the metal oxide nanoparticles, the line width (x) and the line height (y) of the formed line and space pattern, and p/x are listed in Tables 2 and 3.

As the mold, molds for a 50 nm Line & Space pattern, a 70 nm Line & Space pattern, a 100 nm Line & Space pattern, a 250 nm Line & Space pattern, a 300 nm Line & Space pattern, a 350 nm Line & Space pattern, and a 400 nm Line & Space pattern were used.

TABLE 2

| | Curable composition | φ (nm) | x (nm) | y (nm) | φ/x |
|---|---|---|---|---|---|
| Comparative | Composition 1 | 12 | 50 | 100 | 0.24 |
| Example 1 | | | | | |
| Comparative | Composition 1 | 12 | 70 | 140 | 0.17 |
| Example 2 | | | | | |
| Comparative | Composition 1 | 12 | 100 | 170 | 0.12 |
| Example 3 | | | | | |
| Example 1 | Composition 1 | 12 | 250 | 460 | 0.048 |
| Example 2 | Composition 1 | 12 | 300 | 540 | 0.040 |
| Example 3 | Composition 1 | 12 | 350 | 540 | 0.034 |
| Example 4 | Composition 1 | 12 | 400 | 540 | 0.030 |
| Comparative | Composition 2 | 15 | 50 | 100 | 0.28 |
| Example 4 | | | | | |
| Comparative | Composition 2 | 15 | 70 | 140 | 0.20 |
| Example 5 | | | | | |
| Comparative | Composition 2 | 15 | 100 | 170 | 0.14 |
| Example 6 | | | | | |
| Example 5 | Composition 2 | 15 | 250 | 460 | 0.056 |
| Example 6 | Composition 2 | 15 | 300 | 540 | 0.047 |
| Example 7 | Composition 2 | 15 | 350 | 540 | 0.040 |
| Example 8 | Composition 2 | 15 | 400 | 540 | 0.035 |

TABLE 3

| | Curable composition | φ (nm) | x (nm) | y (nm) | φ/x |
|---|---|---|---|---|---|
| Comparative | Composition 3 | 18 | 50 | 100 | 0.32 |
| Example 7 | | | | | |
| Comparative | Composition 3 | 18 | 70 | 140 | 0.23 |
| Example 8 | | | | | |
| Comparative | Composition 3 | 18 | 100 | 170 | 0.16 |
| Example 9 | | | | | |
| Example 9 | Composition 3 | 18 | 250 | 460 | 0.064 |
| Example 10 | Composition 3 | 18 | 300 | 540 | 0.053 |
| Example 11 | Composition 3 | 18 | 350 | 540 | 0.046 |
| Example 12 | Composition 3 | 18 | 400 | 540 | 0.040 |
| Comparative | Composition 4 | 42 | 250 | 460 | 0.168 |
| Example 10 | | | | | |
| Comparative | Composition 4 | 42 | 300 | 540 | 0.140 |
| Example 11 | | | | | |
| Comparative | Composition 4 | 42 | 350 | 540 | 0.120 |
| Example 12 | | | | | |
| Comparative | Composition 4 | 42 | 400 | 540 | 0.105 |
| Example 13 | | | | | |

<Evaluation>

With the photocurable composition of each example, the imprint transferability, the refractive index, and the haze were evaluated by each of the following methods described below. The results are listed in Tables 4 and 5.

[Imprint Transferability]

The pattern was formed as described above, and the transferability of the fine pattern and the filling property were evaluated according to the following criteria.

A: Filling was satisfactory in all lines (in a case of confirmation using an SEM, the mold was filled by 100% and the pattern was able to be transferred)

B: Filling was poor in some lines

C: Filling was poor in all lines

[Refractive Index]

A silicon substrate was spin-coated with the photocurable composition such that the film thickness was adjusted to 600 nm. Next, the composition was prebaked at 90° C. for 1 minute and subjected to a photocuring treatment at an exposure amount of 1 J/cm² (in a vacuum atmosphere of 200 Pa) using an imprint device ST-200 (manufactured by Toshiba Machine Co., Ltd.), thereby obtaining a cured film. The refractive index of the obtained cured film at a wavelength of 530 nm was measured using a spectroscopic ellipsometer M2000 (manufactured by J. A. Woollam Co., Inc.).

TABLE 4

| | φ/x | Refractive index | Filling property |
|---|---|---|---|
| Comparative | 0.24 | 1.79 | C |
| Example 1 | | | |
| Comparative | 0.17 | 1.79 | B |
| Example 2 | | | |
| Comparative | 0.12 | 1.79 | B |
| Example 3 | | | |
| Example 1 | 0.048 | 1.79 | A |
| Example 2 | 0.040 | 1.79 | A |
| Example 3 | 0.034 | 1.79 | A |
| Example 4 | 0.030 | 1.79 | A |
| Comparative | 0.28 | 1.82 | C |
| Example 4 | | | |
| Comparative | 0.20 | 1.82 | C |
| Example 5 | | | |
| Comparative | 0.14 | 1.82 | B |
| Example 6 | | | |
| Example 5 | 0.056 | 1.82 | A |
| Example 6 | 0.047 | 1.82 | A |
| Example 7 | 0.040 | 1.82 | A |
| Example 8 | 0.035 | 1.82 | A |

TABLE 5

| | φ/x | Refractive index | Filling property |
|---|---|---|---|
| Comparative | 0.32 | 1.83 | C |
| Example 7 | | | |
| Comparative | 0.23 | 1.83 | C |
| Example 8 | | | |
| Comparative | 0.16 | 1.83 | B |
| Example 9 | | | |
| Example 9 | 0.064 | 1.83 | B |
| Example 10 | 0.053 | 1.83 | A |
| Example 11 | 0.046 | 1.83 | A |
| Example 12 | 0.040 | 1.83 | A |
| Comparative | 0.168 | 1.85 | C |
| Example 10 | | | |
| Comparative | 0.140 | 1.85 | C |
| Example 11 | | | |
| Comparative | 0.120 | 1.85 | B |
| Example 12 | | | |
| Comparative | 0.105 | 1.85 | B |
| Example 13 | | | |

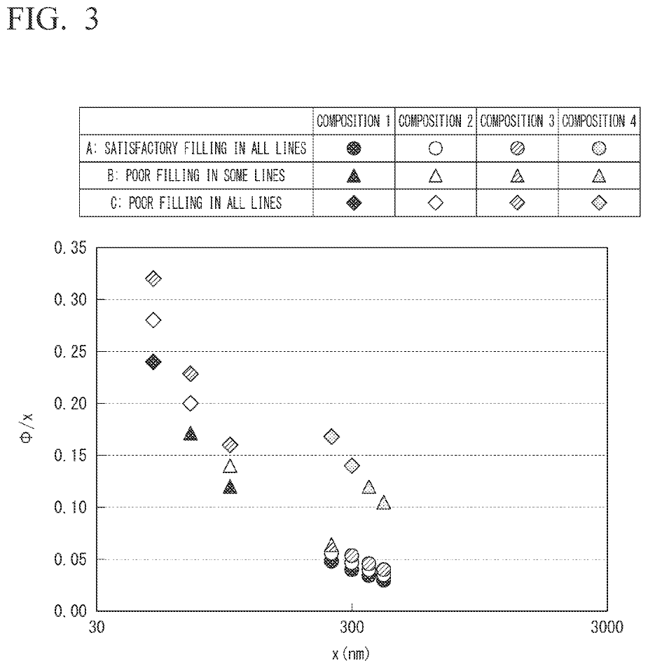

The results of Tables 4 and 5 are shown in FIG. 3. As shown in the results of Tables 4 and 5, most of the filling rates were evaluated as A in the pattern forming methods of Examples 1 to 11 to which the invention of the present application was applied and the filling rates were satisfactory as compared with the pattern forming methods of Comparative Examples 1 to 13. Further, the refractive index was 1.70 or greater in all cases, which was high.

While preferred embodiments of the invention have been described and illustrated above, it should be understood that these are exemplary of the invention and are not to be considered as limiting. Additions, omissions, substitutions, and other modifications can be made without departing from the scope of the invention.

Accordingly, the invention is not to be considered as being limited by the foregoing description and is only limited by the scope of the appended claims.

### EXPLANATION OF REFERENCES

1: Substrate
2: Curable film
2′: Line and space pattern
3: Mold

What is claimed is:

1. A pattern forming method comprising:
forming a curable film on a substrate using a curable composition that contains metal oxide nanoparticles;
pressing a mold having a line and space pattern against the curable film to transfer the line and space pattern to the curable film;
curing the curable film to which the line and space pattern has been transferred while pressing the mold against the curable film, to form a cured film; and
peeling the mold off from the cured film to form a line and space pattern on the substrate,
wherein a line width x of the line and space pattern formed on the substrate in a base portion and a volume average primary particle diameter φ of the metal oxide nanoparticles satisfy an expression of 0.03x<φ<0.08x, and an expression of x≤500 nm.

2. The pattern forming method according to claim 1, wherein the curable composition further contains a polymerizable compound and a polymerization initiator.

3. The pattern forming method according to claim 2, wherein the polymerization initiator is a photopolymerization initiator.

4. The pattern forming method according to claim 1, wherein the curable composition is a photocurable composition.

5. The pattern forming method according to claim 1, wherein a line height y and the line width x of the line and space pattern formed on the substrate satisfy an expression of y≥x.

6. The pattern forming method according to claim 1, wherein the line and space pattern is a rectangular pattern or a slant pattern.

7. A method of producing a curable composition for forming a line and space pattern on a substrate, the method comprising:
selecting metal oxide nanoparticles having a volume average primary particle diameter φ which satisfies an expression of 0.03x<φ<0.08x with respect to a line width x of the line and space pattern in a base portion; and
preparing a curable composition containing the metal oxide nanoparticles, wherein an expression of x≤500 nm is satisfied.

8. The method of producing a curable composition according to claim 7, wherein the preparation the curable composition includes dissolving or dispersing the metal oxide nanoparticles, a polymerizable compound, and a polymerization initiator in a solvent and mixing them.

9. The method of producing a curable composition according to claim 8, wherein the polymerization initiator is a photopolymerization initiator.

10. The method of producing a curable composition according to claim 7, wherein the curable composition is a photocurable composition.

11. The method of producing a curable composition according to claim 7, wherein a line height y and the line width x of the line and space pattern satisfy an expression of y≥x.
